(19) United States
(12) Patent Application Publication
(10) Pub. No.: US 2017/0372926 A1
(43) Pub. Date: Dec. 28, 2017

(54) SUBSTRATE TREATING UNIT, BAKING APPARATUS INCLUDING THE SAME, AND SUBSTRATE TREATING METHOD USING BAKING APPARATUS

(71) Applicant: SEMES CO., LTD., Chungcheongnam-do (KR)

(72) Inventors: Seongsu KIM, Gyeonggi-do (KR); Jong Seok SEO, Chungcheongnam-do (KR)

(21) Appl. No.: 15/627,878

(22) Filed: Jun. 20, 2017

(30) Foreign Application Priority Data
Jun. 24, 2016 (KR) 10-2016-0079241

(51) Int. Cl. H01L 21/67

(52) U.S. Cl. CPC H01L 21/67103; H01L 21/67109

(57) ABSTRACT

Disclosed is a heating unit that heats a substrate. The heating unit includes a housing providing a treatment space in the interior thereof, a heating plate supporting a substrate in the treatment space, a heating member provided in the heating plate and configured to heat-treat the substrate supported by the heating plate, an exhaust member configured to exhaust gas in an interior space of the housing, and an exterior gas supply part installed in the housing and configured to supply exterior gas into the treatment space, wherein the exterior gas supply part includes a plurality of inlets provided in the housing, and a plurality of flow rate adjusting members installed in the inlets, respectively, and configured to adjust flow rates of the exterior gas introduced into the inlets.

### CROSS-REFERENCE TO RELATED APPLICATIONS

A claim for priority under 35 U.S.C. §119 is made to Korean Patent Application No. 10-2016-0079241 filed Jun. 24, 2016, in the Korean Intellectual Property Office, the entire contents of which are hereby incorporated by reference.

### BACKGROUND

Embodiments of the inventive concept described herein relate to an apparatus for treating a substrate, and more particularly to an apparatus for heating a substrate.

Various processes such as photographing, etching, deposition, and cleaning are performed to manufacture a semiconductor device. The photographing process is a process for forming patterns, and plays an important role in high integration of semiconductor devices.

The photographing process mainly includes an application process, an exposure process, and a development process, and baking process are performed before and after the exposure process. The baking process is a process for heat-treating a substrate, and if a substrate is positioned on a heating plate, the substrate is heat-treated through a heater provided in the interior of the heating plate.

FIG. 1 is a sectional view illustrating a general baking unit.

Referring to FIG. 1, the baking unit includes a housing 2 providing a space for performing a baking process in the interior thereof, a heater 3 installed in the interior of the housing 2 to heat a substrate s, and an exhaust line 4.

The fumes generated in a process of performing a baking process is exhausted to the outside through exhaust lines 4, and exterior air is introduced through an inlet 5.

The conventional baking apparatus 1 is implemented in a centrally concentrated exhaustion manner in which exhaust lines 4 are provided at the center of an upper side of the housing 1, and an internal temperature of the housing is lowered in a process in which external gas of low temperature is introduced into the housing through the inlets. Further, according to the conventional baking apparatus, the fumes are attached to inner surfaces of the exhaust lines in a process of discharging the fumes through the exhaust lines, causing the exhaust passages of the exhaust lines to be smaller.

Further, the conventional baking process depends on performance of the heater and control of the heater to improve the uniformity of the thickness of the substrate thin film, and the exterior air introduced into the housing without control is spotlighted as a main cause of determining the thickness of the substrate thin film.

### SUMMARY

Embodiments of the inventive concept provide a heating unit in which the film thicknesses of areas of a substrate may be adjusted by adjusting the flow rates of exterior air introduced into a housing for different zones, a baking apparatus including the same, and a substrate treating method using the baking apparatus.

Embodiments of the inventive concept also provide a heating unit that may restrain air introduced from the outside when a substrate is heated from influencing a temperature of the substrate, a baking apparatus including the same, and a substrate treating method using the baking apparatus.

Embodiments of the inventive concept provide a heating unit that may prevent fumes from being adsorbed again in a substrate treating process, a baking apparatus including the same, and a substrate treating method using the baking apparatus.

The technical objects of the inventive concept are not limited to the above-mentioned ones, and the other unmentioned technical objects will become apparent to those skilled in the art from the following description.

In accordance with an aspect of the inventive concept, there is provided a heating unit including a housing providing a treatment space in the interior thereof, a heating plate supporting a substrate in the treatment space, a heating member provided in the heating plate and configured to heat-treat the substrate supported by the heating plate, an exhaust member configured to exhaust gas in an interior space of the housing, and an exterior gas supply part installed in the housing and configured to supply exterior gas into the treatment space, wherein the exterior gas supply part includes a plurality of inlets provided in the housing, and a plurality of flow rate adjusting members installed in the inlets, respectively, and configured to adjust flow rates of the exterior gas introduced into the inlets.

Each of the flow rate adjusting members may include an opening cover configured to adjust an opening degree of the corresponding inlet.

The exterior gas supply part may further include a plurality of cover driving parts configured to drive the opening covers, and a flow rate control part configured to control the cover driving parts.

The exhaust member may include a guide member installed at an upper portion of the housing to face the heating plate and having an exhaust hole at the center thereof, and an exhaust pipe passing through an upper surface of the housing to be connected to the exhaust hole.

The guide member may be divided into an introduction area spaced apart from an inner wall of an upper surface and an inner wall of a side surface of the chamber such that the exterior gas above the guide member is introduced through the introduction area and an exhaust area through which the exterior gas below the guide member is exhausted.

An area of the guide member may be larger than an area of the substrate when viewed from the top.

Each of the flow rate adjusting members may include a flow rate control valve installed in the corresponding inlet.

The heating unit may further include a plurality of heater installed in the housing and configured to heat the exterior gas introduced into the housing through the inlets, respectively.

The housing may be divided into a plurality of circumferential zones, and the heating unit may further include a heater control part for individually controlling the heaters installed in the zones.

The heaters may be installed on a side wall of the housing.

The housing may include a lower body having an open-topped cylindrical shape and in which the heating plate is locate, an upper body located on the opened upper side of the lower body and coupled to the lower body in an open-bottomed vessel shape to provide a treatment space in the interior thereof, and a body elevating part configured to elevate the upper body.

In accordance with another aspect of the inventive concept, there is provided a baking apparatus including a process chamber providing a heat treating space in the interior thereof and having a slot for carrying a substrate in and out on one side thereof, a cooling plate located in the heat treating space of the process chamber and configured to cool the substrate, and a heating unit configured to heat the substrate, wherein the heating unit includes a housing providing a treatment space in the interior thereof, an exterior gas supply part having an inlet provided in the housing such that exterior gas is introduced into the treatment space and a flow rate adjusting part configured to adjust a flow rate of the exterior gas introduced through the inlet, a heating plate supporting a substrate in the treatment space, a heating member provided in the heating plate and configured to heat-treat the substrate supported by the heating plate, and an exhaust member configured to exhaust gas in an interior space of the housing,

Each of the flow rate adjusting members may include an opening cover configured to adjust an opening degree of the inlet, and the exterior gas supply part may include a cover driving part configured to drive the opening cover, and a flow rate control part configured to control the cover driving part.

The exhaust member may include a guide member installed at an upper portion of the housing to face the heating plate and having an exhaust hole at the center thereof, and an exhaust pipe passing through an upper surface of the housing to be connected to the exhaust hole, and the guide member may be divided into an introduction area spaced apart from an inner wall of an upper surface and an inner wall of a side surface of the chamber such that the exterior gas above the guide member is introduced through the introduction area and an exhaust area through which the exterior gas below the guide member is exhausted.

The housing may be divided into a plurality of circumferential zones, and the heating unit may include a plurality of heaters installed in the zones and configured to heat the exterior gas introduced into the housing through the inlets, and a heater control part configured to individually control the heaters.

The heaters may be installed on a side wall of the housing.

Exterior gas introduced into the interior of a hosing through inlets formed in the housing may be provided onto a substrate and exhausted through an exhaust member provided at an upper portion of the housing together with fumes generated from the substrate, and the exterior gas may be introduced into the housing through adjustment of a flow rate of the exterior gas.

The flow rate of the exterior gas may be adjusted by flow rate adjusting part in the inlets.

The exterior gas introduced into the housing through the inlets may be heated before being provided to the substrate.

The exterior gas may be heated by heaters installed in the housing.

The heaters may be circumferentially provided on an inside of a side wall of the housing to be individually controlled.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a sectional view illustrating a general baking unit;

FIG. 2 is a view of the substrate treating facility, viewed from the top;

FIG. 3 is a sectional view of the facility of FIG. 2, taken along line A-A of FIG. 2;

FIG. 4 is a sectional view of the facility of FIG. 2, taken along line B-B of FIG. 1;

FIG. 5 is a sectional view of the facility of FIG. 2, taken along a line C-C of FIG. 2;

FIG. 6 is a plan view illustrating a baking unit according to an embodiment of the inventive concept;

FIG. 7 is a sectional view illustrating a heating unit for performing a heating process of FIG. 6;

FIG. 8 is a plan view illustrating a heating member provided in the interior of the heating plate of FIG. 7;

FIG. 9 is a plan view illustrating an upper body of a housing;

FIG. 10 is an enlarged view illustrating a main part of an exterior gas supply part installed in the upper body;

FIG. 11 is a plan view illustrating heaters installed in the housing; and

FIG. 12 is a view illustrating air currents in the heating unit.

### DETAILED DESCRIPTION

Hereinafter, exemplary embodiments of the inventive concept will be described in more detail with reference to the accompanying drawings. The embodiments of the inventive concept may be modified in various forms, and the scope of the inventive concept should not be construed to be limited to the following embodiments. The embodiments of the inventive concept are provided to describe the inventive concept for those skilled in the art more completely. Accordingly, the shapes of the components of the drawings are exaggerated to emphasize clearer description thereof.

The facility of the present embodiment of the inventive concept may be used to perform a photography process on a substrate such as a semiconductor substrate or a flat display panel. In particular, the facility of the present embodiment may be connected to an exposure apparatus to perform an application process and a development process on a substrate. Hereinafter, a case of using a wafer as a substrate may be described as an example.

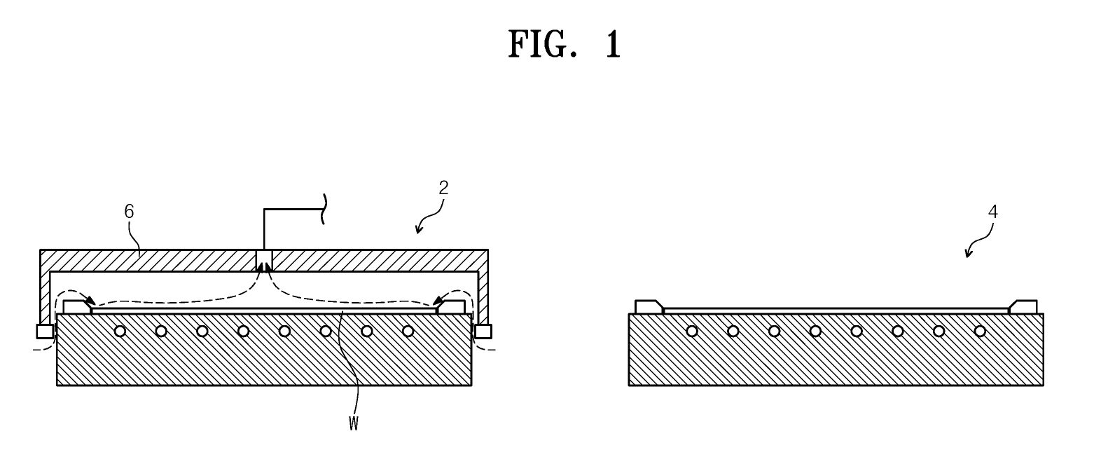

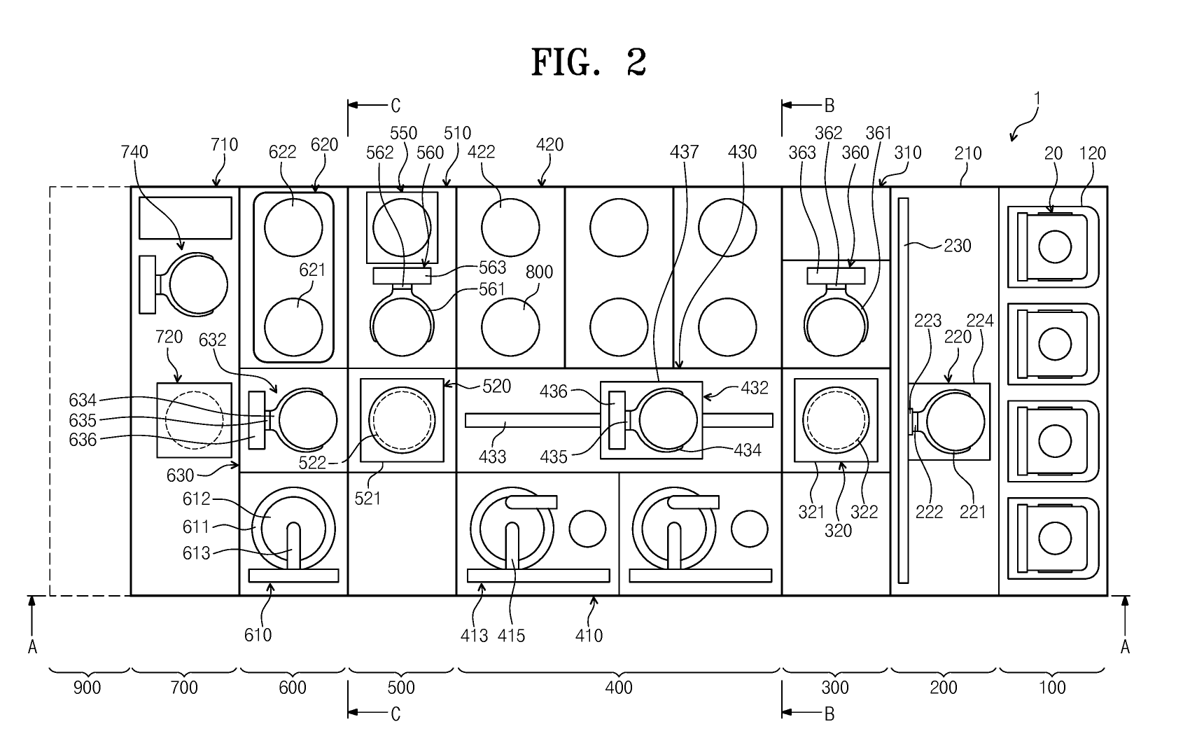

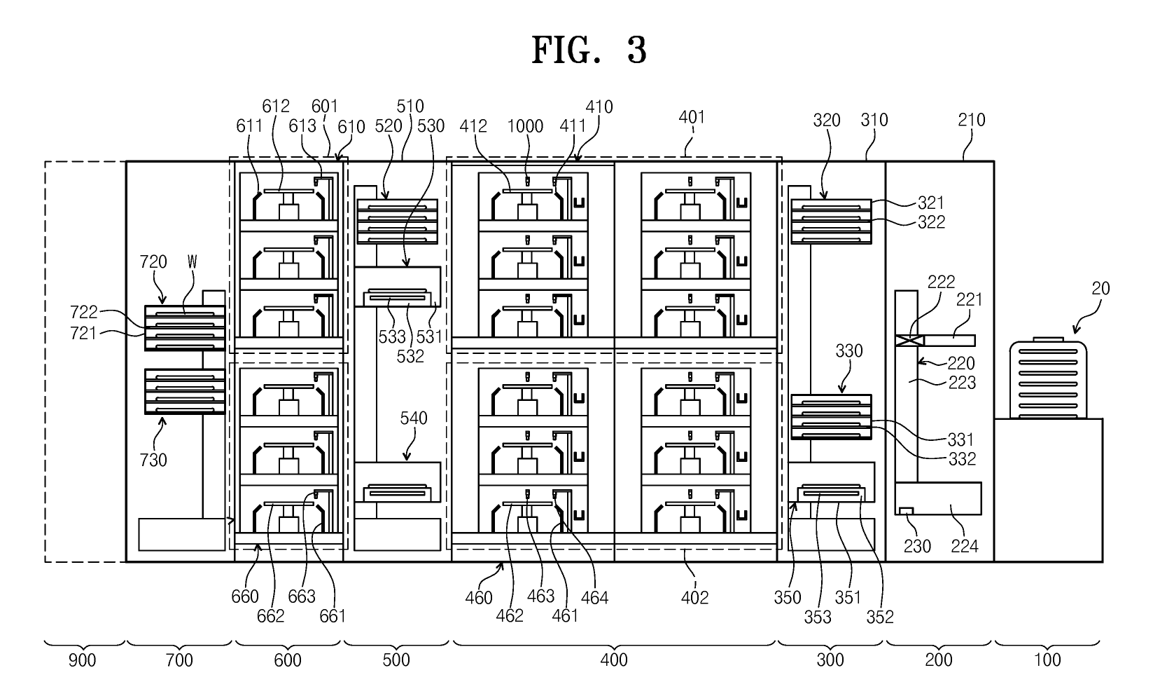

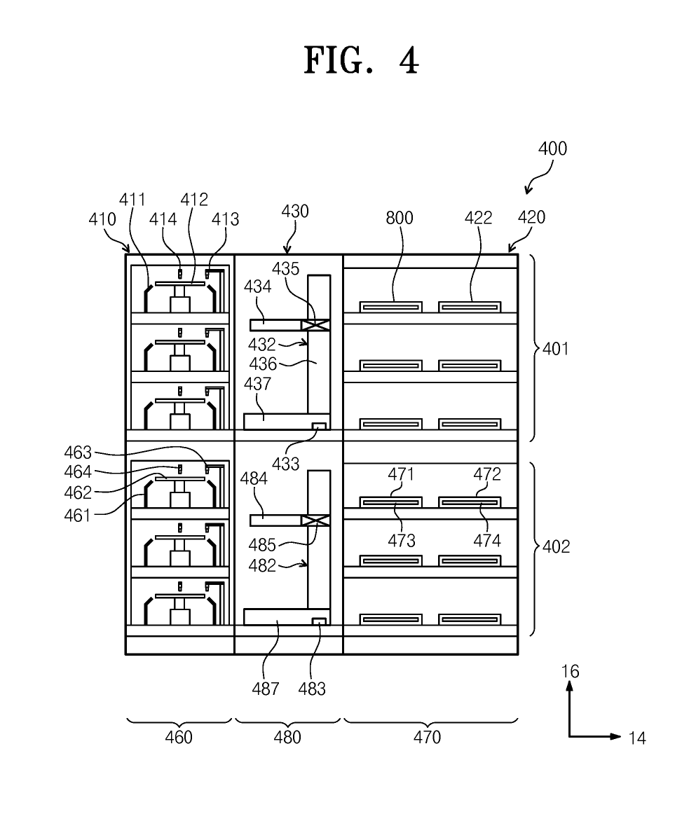

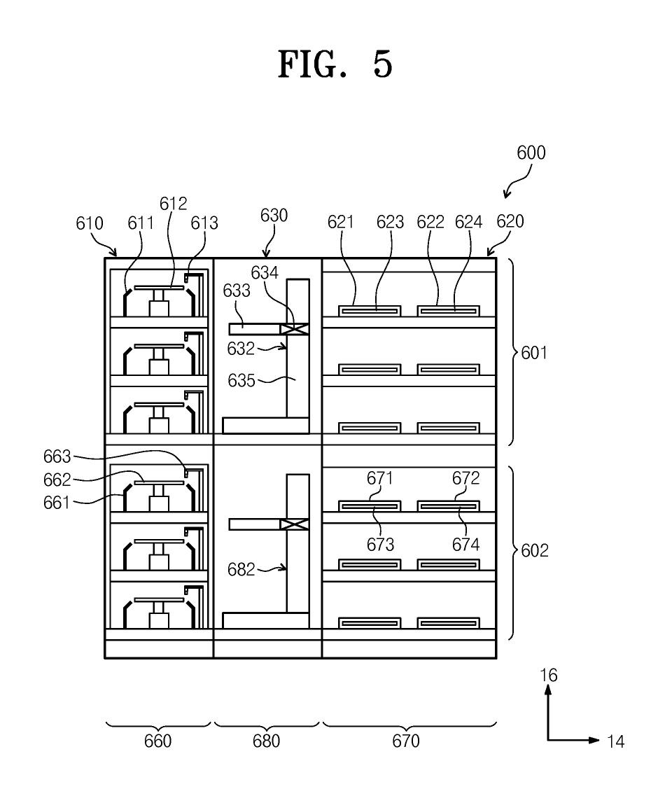

FIGS. 2 to 5 are views schematically illustrating a substrate treating facility according to an embodiment of the inventive concept. FIG. 2 is a view of the substrate treating facility, viewed from the top. FIG. 3 is a sectional view of the facility of FIG. 2, taken along line A-A of FIG. 2. FIG. 4 is a sectional view of the facility of FIG. 2, taken along line B-B of FIG. 1. FIG. 5 is a sectional view of the facility of FIG. 2, taken along a line C-C of FIG. 2.

Referring to FIGS. 2 to 5, the substrate treating facility 1 includes a load port 100, an index module 200, a first buffer module 300, an application/development module 400, a second buffer module 500, a pre/post-exposure treating module 600, and an interface module 700. The load port 100, the index module 200, the first buffer module 300, the application/development module 400, the second buffer module 500, the pre/post-exposure treating module 600, and the interface module 700 are sequentially disposed in a row in one direction.

Hereinafter, a direction in which the load port 100, the index module 200, the first buffer module 300, the application/development module 400, the second buffer module 500, the pre/post-exposure treating module 600, and the interface module 700 are disposed will be referred to as a first direction 12, and a direction that is perpendicular to the first direction 12 when viewed from the top will be referred to as a second direction 14, and a direction that is perpendicular to the first direction 12 and the second direction 14 will be referred to as a third direction 16.

A substrate W is moved while being received in a cassette 20. Then, the cassette 20 has a structure that is sealed from the outside. For example, a front open unified pod (FOUP) that has a door on the front side may be used as the cassette 20.

Hereinafter, the load port 100, the index module 200, the first buffer module 300, the application/development module 400, the second buffer module 500, the pre/post-exposure treating module 600, and the interface module 700 will be described in detail.

The load port 100 has a carrier 120 on which the cassette 20, in which the substrates W are received, is positioned. A plurality of carriers 120 are provided, and are disposed along the second direction 14 in a row. In FIG. 1, four carriers 120 are provided.

The index module 200 feeds a substrate W between the cassette 20 positioned on the carrier 120 of the load port 100 and the first buffer module 300. The index module 200 has a frame 210, an index robot 220, and a guide rail 230. The frame 210 has a substantially rectangular parallelepiped shape having an empty interior, and is disposed between the load port 100 and the first buffer module 300. The frame 210 of the index module 200 may have a height smaller than that of a frame 310 of the first buffer module 300, which will be described below. The index robot 220 and the guide rail 230 are disposed in the frame 210. The index robot 220 has a four-axis driven structure such that a hand 221 that directly handles a substrate W is movable and rotatable in the first direction 12, the second direction 14, and the third direction 16. The index robot 220 has a hand 221, an arm 222, a support 223, and a prop 224. The hand 221 is fixedly installed in the arm 222. The arm 222 has a flexible and rotatable structure. The support 223 is configured such that the lengthwise direction thereof is disposed along the third direction 16. The arm 222 is coupled to the support 223 to be movable along the support 223. The support 223 is fixedly coupled to the prop 224. The guide rail 230 is provided such that the lengthwise direction thereof is disposed along the second direction 14. The prop 224 is coupled to the guide rail 230 to be linearly movable along the guide rail 230. Although not illustrated, the frame 210 is further provided with a door opener that opens and closes a door of the cassette 20.

The first buffer module 300 has a frame 310, a first buffer 320, a second buffer 330, a cooling chamber 350, and a first buffer robot 360. The frame 310 has a rectangular parallelepiped shape having an empty interior, and is disposed between the index module 200 and the application/development module 400. The first buffer 320, the second buffer 330, the cooling chamber 350, and the first buffer robot 360 are situated within the frame 310. The cooling chamber 350, the second buffer 330, and the first buffer 320 are disposed along the third direction 16 sequentially from the bottom. The first buffer 320 is situated at a height corresponding to an application module 401 of the application/development module 400, which will be described below, and the second buffer 330 and the cooling chamber 350 are situated at a height corresponding to a development module 402 of the application/development module 400, which will be described below. The first buffer robot 360 is spaced apart by a predetermined distance in the second direction 14 from the second buffer 330, the cooling chamber 350, and the first buffer 320.

The first buffer 320 and the second buffer 330 temporarily preserve a plurality of substrates W. The second buffer 330 has a housing 331 and a plurality of supports 332. The supports 332 are disposed within the housing 331, and are spaced apart from one another along the third direction 16. One substrate W is positioned on each of the supports 332. The housing 331 has openings (not illustrated) on a side on which the index robot 220 is provided, on a side on which the first buffer robot 360 is provided, and on a side on which a development robot 482 is provided so that the index robot 220, the first buffer robot 360, and a development robot 482 of the development module 402, which will be described below, carries a substrate W into or out of the support 332 in the housing 331. The first buffer 320 has a structure that is substantially similar to that of the second buffer 330. Meanwhile, the housing 321 of the first buffer 320 has an opening on a side on which the first buffer robot 360 is provided and on a side on which an application robot 432 situated in the application module 401, which will be described below, is provided. The number of supports 322 provided for the first buffer 320 and the number of supports 332 provided for the second buffer 330 may be the same or different. According to an embodiment, the number of the supports 332 provided for the second buffer 330 may be larger than the number of the supports 332 provided for the first buffer 320.

The first buffer robot 360 feeds a substrate W between the first buffer 320 and the second buffer 330. The first buffer robot 360 has a hand 361, an arm 362, and a support 363. The hand 361 is fixedly installed in the arm 362. The arm 362 has a flexible structure, and allows the hand 361 to be moved along the second direction 14. The arm 362 is coupled to the support 363 to be linearly movable in the third direction 16 along the support 363. The support 363 has a length extending from a location corresponding to the second buffer 330 to a location corresponding to the first buffer 320. The support 363 may be provided to extend longer upwards or downwards. The first buffer robot 360 may be provided such that the hand 361 is simply two-axis driven along the second direction 14 and the third direction 16.

The cooling chamber 350 cools a substrate W. The cooling chamber 350 has a housing 351 and a cooling plate 352. The cooling plate 352 has a cooling unit 353 that cools an upper surface thereof on which a substrate W is positioned and the substrate W. Various types such as a cooling type using cooling water and a cooling type using a thermoelectric element may be used as the cooling unit 353. A lift pin assembly (not illustrated) that locates a substrate W on the cooling plate 352 may be provided in the cooling chamber 350. The housing 351 has openings (not illustrated) on a side on which the index robot 220 is provided and on a side on which the development robot 482 is provided so that the index robot 220 and the development robot 482 provided for the development robot 402, which will be described below, carry a substrate W into or out of the cooling plate 352. Doors (not illustrated) that open and close the aforementioned openings may be provided in the cooling chamber 350.

The application/development module 400 performs a process of applying a photoresist onto a substrate W before an exposure process and a process of developing the substrate W after the exposure process. The application/development module 400 has a substantially rectangular parallelepiped shape. The application/development module 400 has an application module 401 and a development module 402. The application module 401 and the development module 402 may be disposed to be partitioned from each other in different layers. According to an example, the application module 401 is situated on the development module 402.

The application module 401 performs a process of applying a photosensitive liquid such as a photoresist onto a substrate W and a heat treating process of, for example, heating and cooling the substrate W before and after the resist applying process. The application module 401 has a resist applying chamber 410, a baking unit 420, and a carrying chamber 430. The resist applying chamber 410, the baking unit 420, and the carrying chamber 430 are sequentially disposed along the second direction 14. Accordingly, the resist applying chamber 410 and the baking unit 420 are spaced apart from each other in the second direction 14 while the carrying chamber 430 is interposed therebetween. A plurality of resist applying chambers 410 may be provided, and a plurality of resist applying chambers 410 may be provided in each of the first direction 12 and the third direction 16. In the drawings, six resist applying chambers 410 are illustrated as an example. A plurality of baking units 420 may be provided in each of the first direction 12 and the third direction 16. In the drawings, six baking units 420 are illustrated as an example. However, unlike this, a larger number of baking units 420 may be provided.

The carrying chamber 430 is situated in parallel to the first buffer 320 of the first buffer module 300 in the first direction 12. An application robot 432 and a guide rail 433 may be situated in the carrying chamber 430. The carrying chamber 430 has a substantially rectangular shape. The application robot 432 feeds a substrate W between the baking units 420, the resist applying chambers 410, the first buffer 320 of the first buffer module 300, and the first cooling chamber 520 of the second buffer module 500. The guide rail 433 is disposed such that the lengthwise direction thereof is parallel to the first direction 12. The guide rail 433 guides the application robot 432 such that the application robot 432 is linearly moved in the first direction 12. The application robot 432 has a hand 434, an arm 435, a support 436, and a prop 437. The hand 434 is fixedly installed in the arm 435. The arm 435 has a flexible structure such that the hand 434 is movable horizontally. The support 436 is provided such that the lengthwise direction thereof is disposed along the third direction 16. The arm 435 is coupled to the support 436 to be linearly movable in the third direction 16 along the support 436. The support 436 is fixedly coupled to the prop 437, and the prop 437 is coupled to the guide rail 433 to be movable along the guide rail 433.

The resist applying chambers 410 have the same structure. However, the types of photoresists used in the resist applying chambers 410 may be different. As an example, the photoresist may be a chemical amplification resist. The resist applying chamber 410 applies a photoresist onto the substrate W. The resist applying chamber 410 has a housing 411, a support plate 412, and a nozzle 413. The housing 411 has an open-topped cup shape. The support plate 412 is situated in the housing 411, and supports the substrate W. The support plate 412 may be provided to be rotatable. The nozzle 413 supplies a photoresist onto the substrate W positioned on the support plate 412. The nozzle 413 has a circular pipe shape, and may supply a photoresist to the center of the substrate W. Optionally, the nozzle 413 may have a length corresponding to the diameter of the substrate W, and the discharge hole of the nozzle 413 may be a slit. Further, additionally, a nozzle 414 for supplying a cleaning liquid such as deionized water to clean a surface of the substrate W, to which the photoresist is applied, may be further provided in the resist applying chamber 410.

The baking unit 420 heat-treats the substrate W. For example, the baking units 420 perform a prebake process of eliminating organic substances and moisture on the surface of the substrate W by heating the substrate W at a predetermined temperature before a photoresist is applied or a soft bake process performed after a photoresist is applied onto the substrate W, and performs a cooling process of cooling the substrate W after the heating processes.

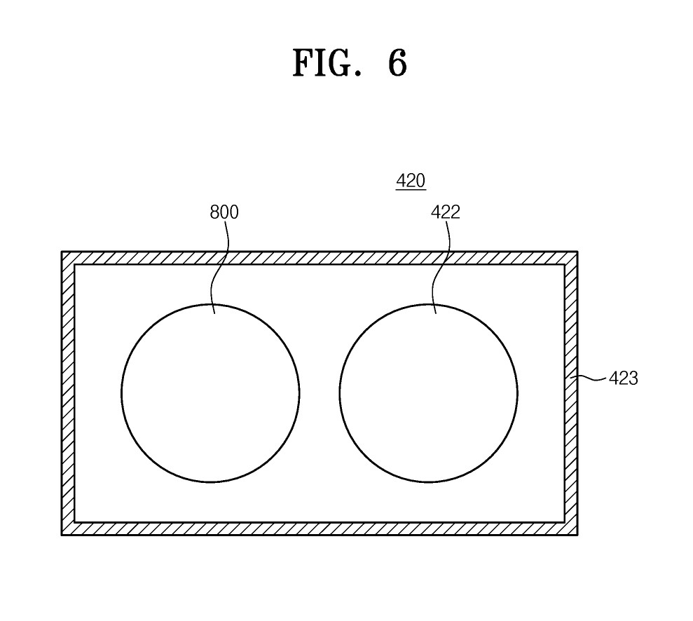

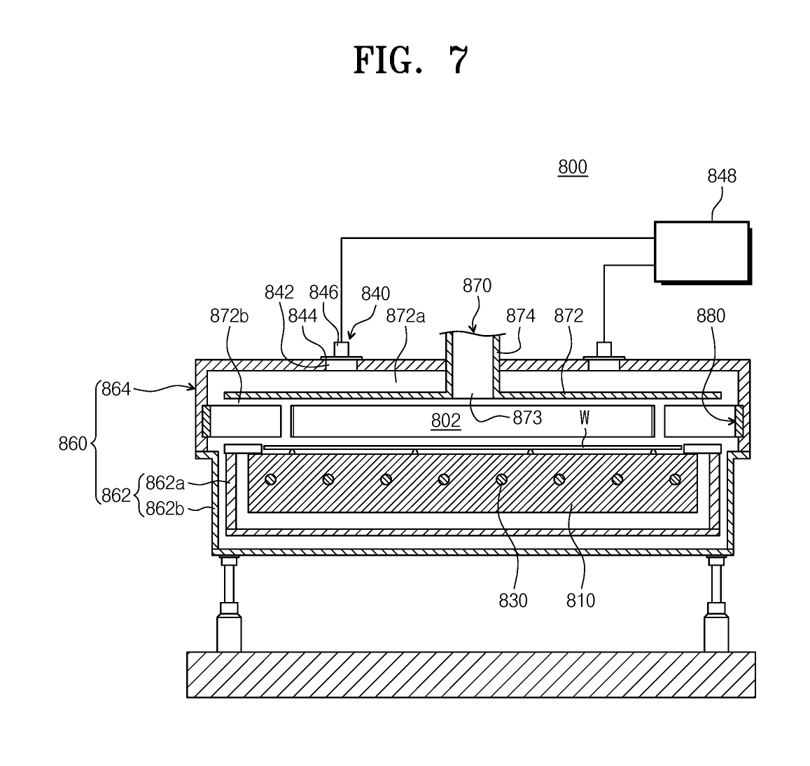

FIG. 6 is a plan view illustrating a baking unit according to an embodiment of the inventive concept. FIG. 7 is a sectional view illustrating a heating unit for performing a heating process of FIG. 6.

Referring to FIGS. 6 and 7, the baking unit 420 may include a process chamber 423, a cooling plate 422, and a heating unit 800.

The process chamber 423 provides a heat treating space 802 in the interior thereof. The process chamber 423 may have a rectangular hexahedral shape. The cooling plate 422 may cool the substrate heated by the heating unit 421. The cooling plate 422 may be located in the heat treating space 802. The cooling plate 422 may have a circular plate shape. Cooling water or a cooling unit, such as a thermoelectric element, is provided in the interior of the cooling plate 422. For example, the cooling plate 422 may cool the heated substrate to a room temperature.

The heating unit 800 heats the substrate. The heating unit 800 may include a housing 860, a heating plate 810, a heating member 830, an exterior gas supply part 840, a heater 880, and an exhaust member 870.

The housing 860 provides a treatment space 802, in which a process of heating the substrate W is performed. The housing 860 includes a lower body 862, an upper body 864, and a driver (not illustrated).

The lower body 862 may have an open-topped vessel shape. The heating plate 810 and the heating member 830 are located in the lower body 862. The lower body 862 includes dual insulation covers to prevent devices located around the heating plate 810 from being thermally deformed. The dual insulation covers 862a and 862b minimize the peripheral devices of the heating plate 810 from being exposed to heat of high temperature generated by the heating member 830. The dual insulation covers 862a and 862b include a primary insulation cover 862a and a secondary insulation cover 862b, and the primary insulation cover 862a and the secondary insulation cover 862b may be spaced apart from each other.

The upper body 864 has a bottom-topped vessel shape. The upper body 864 is combined with the lower body 862 to define a treatment space 802 therebetween. The upper body 864 has a diameter that is larger than that of the lower body 862. The upper body 864 is located above the lower body 862. The upper body 864 may be moved upwards and downwards by the driver. The upper body 864 may be moved upwards and downwards to be moved to a lifted location and a lowered location. Here, the lifted location is a location at which the upper body 864 and the lower body 862 are spaced apart from each other, and the lowered location is a location at which the upper body 864 and the lower body 862 contact each other. At the lowered location, an aperture between the upper body 864 and the lower body 862 are blocked. Accordingly, if the upper body 864 is moved to the lowered location, a treatment space 802 is formed by the upper body 864, the lower body 862, and the heating plate 810.

Although not illustrated, the housing 860 may include a sealing member for preventing exterior air from being introduced into the treatment space. As an example, the sealing member may seal an aperture between the lower body 862 and the upper body 864.

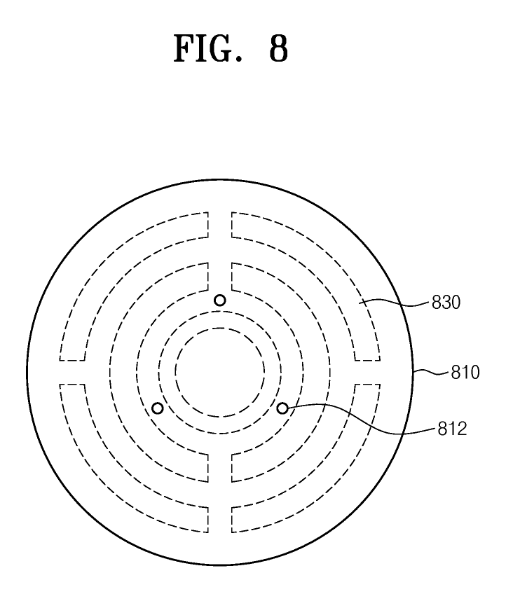

The heating plate 810 may be located in the heat treating space 802. The heating plate 810 is located on one side of the cooling plate 422. The heating plate 810 is provided to have a circular plate shape. An upper surface of the heating plate 810 is provided as a support area, on which the substrate W is positioned. Referring to FIG. 8, a plurality of pin holes 812 are formed on an upper surface of the heating plate 810. For example, three pin holes 812 may be provided. The pin holes 812 are located to be spaced apart from each other along a circumferential direction of the heating plate 810. The pin holes 812 are spaced apart from each other at the same interval. A lift pin (not illustrated) is provided in each of the pin holes 812. The lift pin may be moved upwards and downwards by a driving member (not illustrated).

The heating member 830 heats the substrate W positioned on the heating plate 810 to a preset temperature. FIG. 8 is a transverse sectional view illustrating a heating member provided in the interior of the heating plate of FIG. 7. Referring to FIG. 8, the heating member 830 includes a plurality of heat emitting bodies 830. The heat emitting bodies 830 are located in the interior of the heating plate 810. The heat emitting bodies 830 are located on the same plane. The heat emitting bodies 830 heat different areas of the heating plate 810. The different areas of the heating plate 810 are provided as heating zones heated by the heat emitting bodies 830. The heating zones one-to-one correspond to the heat emitting bodies 830. For example, fifteen heating zones may be provided. For example, the heating member 830 may be a thermoelectric element, a heating wire, or a surface heating emitting body.

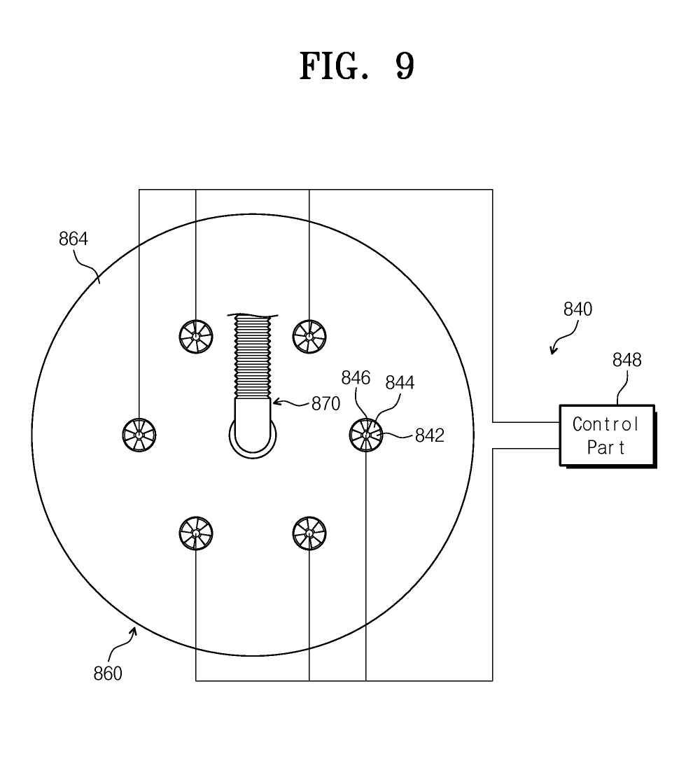

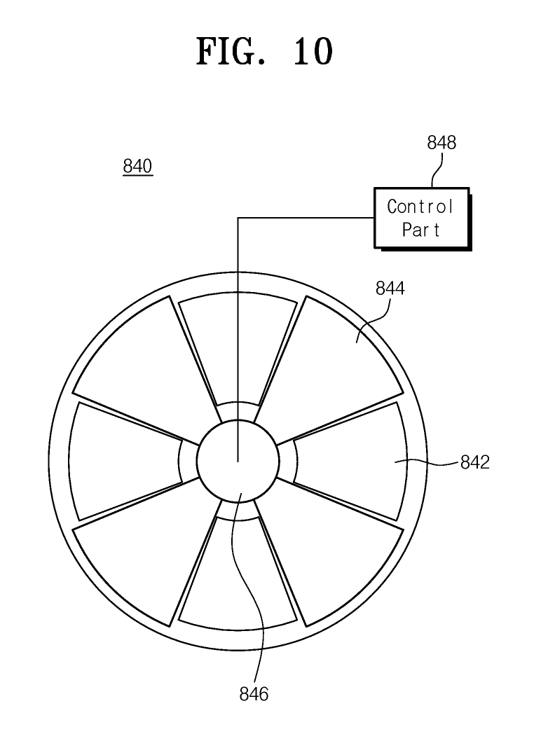

FIG. 9 is a plan view illustrating an upper body of a housing. FIG. 10 is an enlarged view illustrating a main part of an exterior gas supply part installed in the upper body.

Referring to FIGS. 9 and 10, the exterior gas supply part 840 is provided on an upper surface of the upper body 864. Exterior gas is introduced into the treatment space 802 of the housing through the exterior gas supply part 840, and the introduced exterior gas is exhausted to the exhaust member 870 together with fumes generated on the substrate.

The exterior gas supply part 840 may include a plurality of inlets 842, a plurality of opening covers 844 that are flow rate adjusting members, a plurality of cover driving parts 846, and a flow rate control part 848.

A plurality of inlets 842 may be provided on an upper surface of the upper body 864. According to an example, when viewed from the top, the inlets 842 may be sequentially arranged along a circumferential direction of the upper body 864 with respect to the center of the upper surface of the upper body 864. The flow rate adjusting members may be installed in the inlets 842, respectively. The flow rate adjusting members are adapted to adjust the flow rates of the exterior gas introduced into the inlets 842, and as an example, may be the opening covers 844 configured to adjust opening degrees of the inlets 842, respectively. The opening covers 844 may be rotated by the cover driving parts 846 to open and close the inlets 842. The cover driving parts 846 are controlled by the flow rate control part 848. In the embodiment, the flow rate adjusting members may be flow control valves, in addition to the opening covers, and the flow rate adjusting members configured to adjust the opening degrees of the inlets may be various devices, in addition to the above-mentioned units.

In the embodiment, eight inlets 842 may be provided in the upper body 864, and the inlets 842 may individually control the flow rates of the exterior gas introduced into the housing 860 through rotation of the opening covers 844. Accordingly, the treatment space of the housing 860 is divided into eight areas, and air currents on the substrate may be controlled by adjusting the flow rates of the exterior gas introduced into the areas. The thickness of the substrate thin film may be adjusted by controlling air currents on the substrate for a plurality of areas.

Although it has been described in the embodiment that the inlets 842 are formed on the upper surface of the upper body 864, the inventive concept is not limited thereto and the inlets 842 may be formed on a side surface of the upper body 864.

The exhaust member 870 may include a guide member 872 and an exhaust pipe 874.

The guide member 872 faces the heating plate 810, and is spaced apart from an inner wall of an upper surface and an inner wall of a side surface of the upper body 864. Accordingly, an upper space 804 above the guide member 872 and a lower space 806 below the guide member 872 may be formed in the treatment space 802 of the housing 860. The upper space 804 may be an introduction area in which exterior gas introduced through the exterior gas supply part 840 flows, and the lower space 806 may be an exhaust area in which the gas introduced to an upper part of the substrate and fumes generated by the substrate are exhausted.

The guide member 872 may be a circular plate having an exhaust hole 873 at the center thereof, and the exhaust pipe 874 passes through the upper body 864 to be connected to the exhaust hole 873. Further, the size of the guide member 872 may be larger than the size of the substrate.

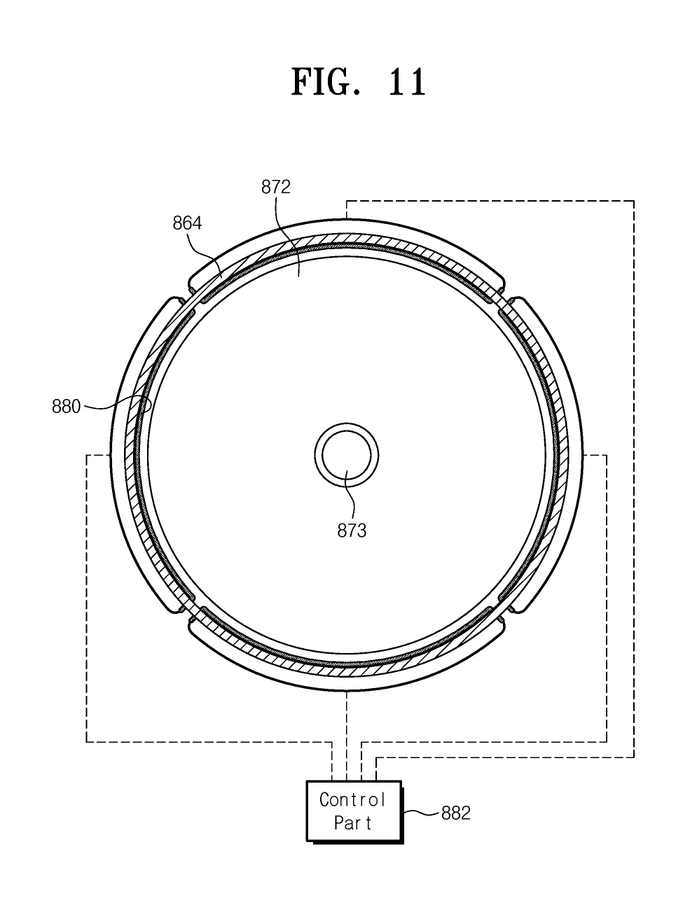

FIG. 11 is a plan view illustrating heaters installed in the housing.

Referring to FIGS. 7 and 11, the heaters 880 may be installed in the housing 860. The housing 860 may be divided into a plurality of circumferential zones, and the heaters 880 may be installed in the zones, respectively. As an example, the heaters 880 may be installed in a side wall of the housing 860 corresponding to a path along which exterior gas is introduced to flow. The heaters 880 may be individually controlled by the heater control part 882. The heater control part 882 may control the heaters 880 such that the temperatures of the corresponding areas satisfy the purpose of the heaters 880.

In this way, the temperatures of the exterior gas introduced into the interior of the housing 860 through the exterior gas supply part 840 may increase while the exterior gas passes through the corresponding areas in which the heaters 880 are installed. As the heaters 880 increase the temperature of the exterior gas, the temperature of the gas exhausted through the exhaust member also increases so that the fumes may be prevented from being adsorbed to the housing 860 or the exhaust pipe 874.

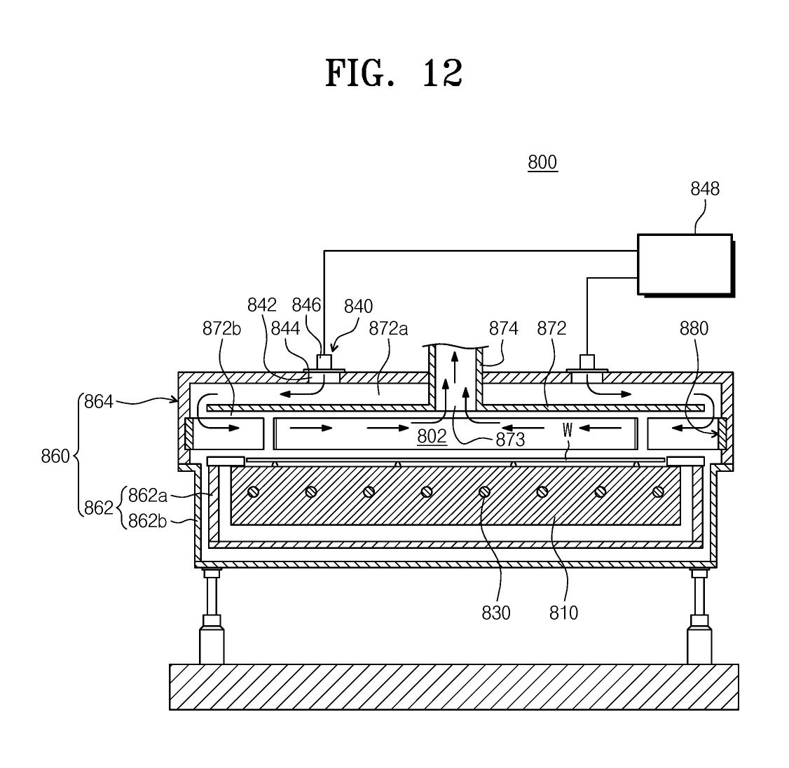

FIG. 12 is a view illustrating air currents in the heating unit.

Referring to FIG. 12, the exterior gas introduced through the exterior gas supply part 840 is not directly introduced to the upper surface of the substrate W but flows to a periphery of the treatment space 802 along the upper space 872a provided by the guide member 872. The exterior gas is introduced into the lower space 872b of the guide member 872 while the temperature of the exterior gas is increased by the heaters 880. Further, while the baking process is performed, the gas of the lower space 872b and the fumes evaporated from the substrate are discharged through the exhaust pipe 874.

Referring to FIGS. 2 to 5 again, the development module 402 includes a process of eliminating a photoresist by supplying a development liquid to obtain a pattern on the substrate W, and a heat treating process, such as heating and cooling, which are performed on the substrate W before and after the development process. The development module 402 has a development chamber 460, a baking unit 470, and a carrying chamber 480. The development chamber 460, the baking unit 470, and the carrying chamber 480 are sequentially disposed along the second direction 14. Accordingly, the development chamber 460 and the baking unit 470 are spaced apart from each other in the second direction 14 while the carrying chamber 480 is interposed therebetween. A plurality of development chambers 460 may be provided, and a plurality of development chambers 460 may be provided in each of the first direction 12 and the third direction 16. In the drawings, six development chambers 460 are illustrated as an example. A plurality of baking units 470 may be provided in each of the first direction 12 and the third direction 16. In the drawings, six baking units 470 are illustrated as an example. However, unlike this, a larger number of baking units 470 may be provided.

The carrying chamber 480 is situated in parallel to the second buffer 330 of the first buffer module 300 in the first direction 12. A development robot 482 and a guide rail 483 may be situated in the carrying chamber 480. The carrying chamber 480 has a substantially rectangular shape. The development robot 482 feeds the substrate W between the baking units 470, the development chambers 460, the second buffer 330 and the cooling chamber 350 of the first buffer module 300, and the second cooling chamber 540 of the second buffer module 500. The guide rail 483 is disposed such that the lengthwise direction thereof is parallel to the first direction 12. The guide rail 483 guides the development robot 482 such that the development robot 432 is linearly moved in the first direction 12. The development robot 482 has a hand 484, an arm 485, a support 486, and a prop 487. The hand 484 is fixedly installed in the arm 485. The arm 485 has a flexible structure such that the hand 484 is movable horizontally. The support 486 is provided such that the lengthwise direction thereof is disposed along the third direction 16. The arm 485 is coupled to the support 486 to be linearly movable in the third direction 16 along the support 486. The support 486 is fixedly coupled to the prop 487. The prop 487 is coupled to the guide rail 483 to be linearly movable along the guide rail 483.

The development chambers 460 have the same structure. However, the types of development liquids used in the development chambers 460 may be different. The development chambers 460 eliminate an area of the photoresist on the substrate W, to which light is irradiated. Then, an area of the protection film, to which light is irradiated, is eliminated together. Optionally, only an area of the photoresist and the protection film, to which light is not irradiated, may be eliminated according to the type of the used photoresist.

The development chamber 460 has a housing 461, a support plate 462, and a nozzle 463. The housing 461 has an open-topped cup shape. The support plate 462 is situated in the housing 461, and supports the substrate W. The support plate 462 may be provided to be rotatable. The nozzle 463 supplies a development liquid onto the substrate W positioned on the support plate 462. The nozzle 463 may have a circular pipe shape, and may supply a development liquid to the center of the substrate W. Optionally, the nozzle 463 may have a length corresponding to the diameter of the substrate W, and the discharge hole of the nozzle 463 may be a slit. The development chamber 460 may be further provided with a nozzle 464 that supplies a cleaning liquid such as deionized water to clean the surface of the substrate W, to which the development liquid is additionally supplied.

The baking unit 470 of the development module 402 heat-treats the substrate W. For example, the baking units 470 may perform a post bake process of heating the substrate W before the development process, a hard bake process of heating the substrate W after the development process, and a cooling process of cooling the heated substrate W after the bake process. The baking unit 470 has a cooling plate 471 and a heating plate 472. The cooling plate 471 is provided with a cooling unit 473 such as cooling water or a thermoelectric element. The heating plate 472 is provided with a heating unit 474 such as a heating wire or a thermoelectric element. The cooling plate 471 and the heating plate 472 may be provided in one baking unit 470. Optionally, some of the baking units 470 may include only a cooling plate 471, and some of the bake chambers 470 may include only a heating plate 472. Because the baking units 470 of the development module 402 have the same configuration as that of the baking chambers of the application module 401, a detailed description thereof will be omitted.

The second buffer module 500 is provided as a passage through which the substrate W is transported, between the application/development module 400 and the pre/post-exposure module 600. The second buffer module 500 performs a process such as a cooling process or an edge exposing process on the substrate W. The second buffer module 500 has a frame 510, a buffer 520, a first cooling chamber 530, a second cooling chamber 540, an edge exposing chamber 550, and a second buffer robot 560. The frame 510 has a rectangular parallelepiped shape. The buffer 520, the first cooling chamber 530, the second cooling chamber 540, the edge exposing chamber 550, and the second buffer robot 560 are situated in the frame 510. The buffer 520, the first cooling chamber 530, and the edge exposing chamber 550 are disposed at a height corresponding to the application module 401. The second cooling chamber 540 is disposed at a height corresponding to the development module 402. The buffer 520, the first cooling chamber 530, and the second cooling chamber 540 are disposed in a row along the third direction 16. When viewed from the top, the buffer 520 is disposed along the carrying chamber 430 of the application module 401 in the first direction 12. The edge exposing chamber 550 is spaced apart from the buffer 520 or the first cooling chamber 530 by a predetermined distance in the second direction 14.

The second buffer robot 560 transports the substrate W between the buffer 520, the first cooling chamber 530, and the edge exposing chamber 550. The second buffer robot 560 is situated between the edge exposing chamber 550 and the buffer 520. The second buffer robot 560 may have a structure that is similar to that of the first buffer robot 360. The first cooling chamber 530 and the edge exposing chamber 550 perform a succeeding process on the substrates W, on which the application module 401 has performed a process. The first cooling chamber 530 cools the substrate W, on which the application module 401 has performed a process. The first cooling chamber 530 has a structure similar to that of the cooling chamber 350 of the first buffer module 300. The edge exposing chamber 550 exposes peripheries of the substrates W, on which the first cooling chamber 530 has performed a cooling process. The buffer 520 temporarily preserves the substrates W before the substrates W, on which the edge exposing chamber 550 has performed a process, are transported to a pre-treatment module 601, which will be described below. The second cooling chamber 540 cools the substrates W before the substrates W, on which a post-treatment module 602, which will be described below, has performed a process, are transported to the development module 402. The second buffer module 500 may further have a buffer at a height corresponding to the development module 402. In this case, the substrates W, on which the post-treatment module 602 has performed a process, may be transported to the development module 402 after being temporarily preserved in the added buffer.

When the exposure apparatus 900 performs an immersion/exposure process, the pre/post-exposure module 600 may perform a process of applying a protective film that protects the photoresist film applied to the substrate W during the immersion/exposure process. The pre/post-exposure module 600 may perform a process of cleaning the substrate W after the exposure process. Furthermore, when the application process is performed by using a chemical amplification resist, the pre/post-exposure module 600 may perform a bake process after the exposure process.

The pre/post-exposure module 600 has a pre-treatment module 601 and a post-treatment module 602. The pre-treatment module 601 performs a process of treating the substrate W before the exposure process, and the post-treatment module 602 performs a process of treating the substrate W after the exposure process. The pre-treatment module 601 and the post-treatment module 602 may be disposed to be partitioned from each other in different layers. According to an example, the pre-treatment module 601 is situated on the post-treatment module 602. The pre-treatment module 601 has the same height as that of the application module 401. The post-treatment module 602 has the same height as that of the development module 402. The pre-treatment module 601 has a protective film applying chamber 610, a baking unit 620, and a carrying chamber 630. The protective film applying chamber 610, the carrying chamber 630, and the baking unit 620 are sequentially disposed along the second direction 14. Accordingly, the protective film applying chamber 610 and the baking unit 620 are spaced apart from each other in the second direction 14 while the carrying chamber 630 is interposed therebetween. A plurality of protective film applying chambers 610 are provided, and the plurality of protective film applying chambers 610 are disposed along the third direction 16 to form different layers. Optionally, a plurality of protective film applying chambers 610 may be provided in each of the first direction 12 and the third direction 16. A plurality of baking units 620 are provided, and the plurality of bake chambers 610 are disposed along the third direction 16 to form different layers. Optionally, a plurality of baking units 620 may be provided in each of the first direction 12 and the third direction 16.

The carrying chamber 630 is situated in parallel to the first cooling chamber 530 of the second buffer module 500 in the first direction 12. A pre-treatment robot 632 is situated in the carrying chamber 630. The carrying chamber 630 has a substantially square or rectangular shape. The pre-treatment robot 632 feeds the substrate W between the protective film applying chambers 610, the baking units 620, the buffer 520 of the second buffer module 500, and a first buffer 720 of the interface module 700, which will be described below. The pre-treatment robot 632 has a hand 633, an arm 634, and a support 635. The hand 633 is fixedly installed in the arm 634. The arm 634 has a flexible and rotatable structure. The arm 634 is coupled to the support 635 to be linearly movable in the third direction 16 along the support 635.

The protective film applying chamber 610 applies a protective film that protects a resist film during the immersion/exposure process, onto the substrate W. The protective film applying chamber 610 has a housing 611, a support plate 612, and a nozzle 613. The housing 611 has an open-topped cup shape. The support plate 612 is situated in the housing 611, and supports the substrate W. The support plate 612 may be provided to be rotatable. The nozzle 613 supplies a protection liquid for forming a protective film onto the substrate W positioned on the support plate 612. The nozzle 613 has a circular pipe shape, and may supply a protection liquid to the center of the substrate W. Optionally, the nozzle 613 may have a length corresponding to the diameter of the substrate W, and the discharge hole of the nozzle 613 may be a slit. In this case, the support plate 612 may be provided in a fixed state. The protection liquid includes an expandable material. The protection liquid may be a material that has a low affinity for a photoresist and water. For example, the protection liquid may include a fluorine-based solvent. The protective film applying chamber 610 supplies a protection liquid to a central area of the substrate W while rotating the substrate W positioned on the support plate 612.

The baking unit 620 heat-treats the substrate W, to which the protective film is applied. The baking unit 620 has a cooling plate 621 and a heating plate 622. The cooling plate 621 is provided with a cooling unit 623 such as cooling water or a thermoelectric element. The heating plate 622 is provided with a heating unit 624 such as a heating wire or a thermoelectric element. The heating plate 622 and the cooling plate 621 may be provided in one baking unit 620. Optionally, some of the baking units 620 may include only a heating plate 622, and some of the bake chambers 620 may include only a cooling plate 621.

The post-treatment module 602 has a cleaning chamber 660, a post-exposure baking unit 670, and a carrying chamber 680. The cleaning chamber 660, the carrying chamber 680, and the post-exposure baking unit 670 are sequentially disposed along the second direction 14. Accordingly, the cleaning chamber 660 and the post-exposure baking unit 670 are spaced apart from each other in the second direction 14 while the carrying chamber 680 is interposed therebetween. A plurality of cleaning chambers 660 are provided, and the plurality of cleaning chambers 610 are disposed along the third direction 16 to form different layers. Optionally, a plurality of cleaning chambers 660 may be provided in each of the first direction 12 and the third direction 16. A plurality of post-exposure baking units 670 are provided, and the plurality of post-exposure bake chambers 610 are disposed along the third direction 16 to form different layers. Optionally, a plurality of post-exposure baking units 670 may be provided in each of the first direction 12 and the third direction 16.

When viewed from the top, the carrying chamber 680 is situated in parallel to the second cooling chamber 540 of the second buffer module 500 in the first direction 12. The carrying chamber 680 has a substantially square or rectangular shape. A post-treatment robot 682 is situated in the carrying chamber 680. The post-treatment robot 682 transports the substrate W between the cleaning chambers 660, the post-exposure baking units 670, the second cooling chamber 540 of the second buffer module 500, and a second buffer 730 of the interface module 700, which will be described below. The post-treatment robot 682 provided in the post-treatment module 602 may have the same structure as that of the pre-treatment robot 632 provided in the pre-treatment module 601.

The cleaning chamber 660 cleans the substrate W after the exposure process. The cleaning chamber 660 has a housing 661, a support plate 662, and a nozzle 663. The housing 661 has an open-topped cup shape. The support plate 662 is situated in the housing 661, and supports the substrate W. The support plate 662 may be provided to be rotatable. The nozzle 663 supplies a cleaning liquid onto the substrate W positioned on the support plate 662. The cleaning liquid may be water such as deionized water. The cleaning chamber 660 supplies a cleaning liquid to a central area of the substrate W while rotating the substrate W positioned on the support plate 662. Optionally, the nozzle 663 may be linearly moved or rotated from a central area to a peripheral area of the substrate W while the substrate W is rotated.

After the exposure process, the bake unit 670 heats the substrate W, on which the exposure process has been performed, by using a far infrared ray. After the exposure process, in the bake process, the substrate W is heated to finish a property change of the photoresist by amplifying acid produced in the photoresist through the exposure process. After the exposure process, the baking unit 670 has a heating plate 672. The heating plate 672 is provided with a heating unit 674 such as a heating wire or a thermoelectric element. After the exposure process, the baking unit 670 may be further provided with a cooling plate 671 in the interior thereof. The cooling plate 671 is provided with a cooling unit 673 such as cooling water or a thermoelectric element. Optionally, a baking unit having only a cooling plate 671 may be further provided.

As described above, the pre/post-exposure module 600 is provided such that the pre-treatment module 601 and the post-treatment module 602 are completely separated from each other. The carrying chamber 630 of the pre-treatment module 601 and the carrying chamber 680 of the post-treatment module 602 may have the same size, and may completely overlap each other when viewed from the top. The protective film applying chamber 610 and the cleaning chamber 660 may have the same size, and may completely overlap with each other when viewed from the top. The baking unit 620 and the post-exposure baking unit 670 may have the same size, and may completely overlap with each other when viewed from the top.

The interface module 700 feeds the substrate W between the pre/post-exposure module 600 and the exposure apparatus 900. The interface module 700 has a frame 710, a first buffer 720, a second buffer 730, and an interface robot 740. The first buffer 720, the second buffer 730, and the interface robot 740 are situated within the frame 710. The first buffer 720 and the second buffer 730 are spaced apart from each other by a predetermined distance, and may be stacked. The first buffer 720 is disposed at a location higher than the second buffer 730. The first buffer 720 is situated at a height corresponding to the pre-treatment module 601, and the second buffer 730 is disposed at a height corresponding to the post-treatment module 602. When viewed from the top, the first buffer 720 is disposed along the first direction 12 while forming a row with the carrying chamber 630 of the pre-treatment module 601, and the second buffer 730 is disposed along the first direction 12 forming a row with the carrying chamber 630 of the post-treatment module 602.

The interface robot 740 is situated to be spaced apart from the first buffer 720 and the second buffer 730 in the second direction 14. The interface robot 740 transports the substrate W between the first buffer 720, the second buffer 730, and the exposure apparatus 900. The interface robot 740 has a structure that is substantially similar to that of the second buffer robot 560.

The first buffer 720 temporarily preserves the substrates W, on which the pre-treatment module 601 has performed a process, before they are moved to the exposure apparatus 900. The second buffer 730 temporarily preserves the substrates W, on which the exposure apparatus 900 has completely performed a process, before they are moved to the post-treatment module 602. The first buffer 720 has a housing 721 and a plurality of supports 722. The supports 722 are disposed within the housing 721, and are spaced apart from one another along the third direction 16. One substrate W is positioned on each of the supports 722. The housing 721 has openings (not illustrated) on a side on which the interface robot 740 is provided and on a side on which the pre-treatment robot 721 is provided so that the interface robot 740 and the pre-treatment robot 632 carry a substrate W into or out of the cooling plate 722. The second buffer 730 has a structure that is substantially similar to that of the first buffer 720. Meanwhile, the housing 4531 of the second buffer 730 has openings on a side on which the interface robot 740 is provided and on a side on which the post-treatment robot 682 is provided. The interface module may be provided only with buffers and a robot as described above while a chamber that performs a certain process on a substrate is not provided.

According to the embodiments of the inventive concept, the thicknesses of the substrate for areas may be adjusted by adjusting the flow rates of exterior gas introduced into the housing by the flow rate adjusting member for zones.

According to the embodiments of the inventive concept, the temperature distribution of the substrate may be prevented from being uneven and fumes may be prevented from being adsorbed again, by providing exterior gas introduced into the housing by the flow rate adjusting members to the upper side of the substrate after the exterior gas is heated by the heaters.

What is claimed is:

1. A heating unit comprising:
a housing providing a treatment space in the interior thereof;
a heating plate supporting a substrate in the treatment space;
a heating member provided in the heating plate and configured to heat-treat the substrate supported by the heating plate;
an exhaust member configured to exhaust gas in an interior space of the housing; and
an exterior gas supply part installed in the housing and configured to supply exterior gas into the treatment space,
wherein the exterior gas supply part includes:
a plurality of inlets provided in the housing; and
a plurality of flow rate adjusting members installed in the inlets, respectively, and configured to adjust flow rates of the exterior gas introduced into the inlets.

2. The heating unit of claim 1, wherein each of the flow rate adjusting members includes:
an opening cover configured to adjust an opening degree of the corresponding inlet.

3. The heating unit of claim 2, wherein the exterior gas supply part further includes:
a plurality of cover driving parts configured to drive the opening covers; and
a flow rate control part configured to control the cover driving parts.

4. The heating unit of claim 1, wherein the exhaust member includes:
a guide member installed at an upper portion of the housing to face the heating plate and having an exhaust hole at the center thereof; and
an exhaust pipe passing through an upper surface of the housing to be connected to the exhaust hole.

5. The heating unit of claim 4, wherein the guide member is divided into an introduction area spaced apart from an inner wall of an upper surface and an inner wall of a side surface of the housing such that the exterior gas above the guide member is introduced through the introduction area and an exhaust area through which the exterior gas below the guide member is exhausted.

6. The heating unit of claim 4, wherein an area of the guide member is larger than an area of the substrate when viewed from the top.

7. The heating unit of claim 1, wherein each of the flow rate adjusting members includes:
a flow rate control valve installed in the corresponding inlet.

8. The heating unit of claim 1, further comprising:
a plurality of heater installed in the housing and configured to heat the exterior gas introduced into the housing through the inlets, respectively.

9. The heating unit of claim 8, wherein the housing is divided into a plurality of circumferential zones, and
wherein the heating unit further comprises a heater control part for individually controlling the heaters installed in the zones.

10. The heating unit of claim 8, wherein the heaters are installed on a side wall of the housing.

11. The heating unit of claim 1, wherein the housing includes:
a lower body having an open-topped cylindrical shape and in which the heating plate is located;
an upper body located on the opened upper side of the lower body and coupled to the lower body in an open-bottomed vessel shape to provide a treatment space in the interior thereof; and
a body elevating part configured to elevate the upper body.

12. A baking apparatus comprising:
a process chamber providing a heat treating space in the interior thereof and having a slot for carrying a substrate in and out on one side thereof;
a cooling plate located in the heat treating space of the process chamber and configured to cool the substrate; and
a heating unit configured to heat the substrate,
wherein the heating unit includes:
a housing providing a treatment space in the interior thereof;
an exterior gas supply part having an inlet provided in the housing such that exterior gas is introduced into the treatment space and a flow rate adjusting part configured to adjust a flow rate of the exterior gas introduced through the inlet;
a heating plate supporting a substrate in the treatment space;
a heating member provided in the heating plate and configured to heat-treat the substrate supported by the heating plate; and
an exhaust member configured to exhaust gas in an interior space of the housing;

13. The baking apparatus of claim 12, wherein each of the flow rate adjusting members includes:
an opening cover configured to adjust an opening degree of the inlet, and
wherein the exterior gas supply part includes:
a cover driving part configured to drive the opening cover; and
a flow rate control part configured to control the cover driving part.

14. The baking apparatus of claim 12, wherein the exhaust member includes:
a guide member installed at an upper portion of the housing to face the heating plate and having an exhaust hole at the center thereof; and
an exhaust pipe passing through an upper surface of the housing to be connected to the exhaust hole, and
wherein the guide member is divided into an introduction area spaced apart from an inner wall of an upper surface and an inner wall of a side surface of the housing such that the exterior gas above the guide member is introduced through the introduction area and an exhaust area through which the exterior gas below the guide member is exhausted.

15. The baking apparatus of claim 12, wherein the housing is divided into a plurality of circumferential zones, and
wherein the heating unit includes:
a plurality of heaters installed in the zones and configured to heat the exterior gas introduced into the housing through the inlets; and
a heater control part configured to individually control the heaters.

16. The baking apparatus of claim 15, wherein the heaters are installed on a side wall of the housing.

17. A substrate treating method wherein exterior gas introduced into the interior of a hosing through inlets formed in the housing is provided onto a substrate and exhausted through an exhaust member provided at an upper portion of the housing together with fumes generated from the substrate, and the exterior gas is introduced into the housing through adjustment of a flow rate of the exterior gas.

18. The substrate treating method of claim 17, wherein the flow rate of the exterior gas is adjusted by flow rate adjusting part in the inlets.

19. The substrate treating method of claim 17, wherein the exterior gas introduced into the housing through the inlets is heated before being provided to the substrate.

20. The substrate treating method of claim 19, wherein the exterior gas is heated by heaters installed in the housing.

21. The substrate treating method of claim 20, wherein the heaters are circumferentially provided on an inside of a side wall of the housing to be individually controlled.
